(19) United States
(12) Patent Application Publication
(10) Pub. No.: US 2009/0091367 A1
(43) Pub. Date: Apr. 9, 2009

(54) LEVEL SHIFTER CONCEPT FOR FAST LEVEL TRANSIENT DESIGN

(75) Inventor: Yu-Wen Chiou, Tainan County (TW)

Correspondence Address: J C PATENTS, INC., 4 VENTURE, SUITE 250, IRVINE, CA, 92618, US

(73) Assignee: HIMAX TECHNOLOGIES LIMITED, Tainan County (TW)

(21) Appl. No.: 11/868,424

(22) Filed: Oct. 5, 2007

(51) Int. Cl. H03L 5/00

(52) U.S. Cl. 327/333

(57) ABSTRACT

A driver including a first level shifter group and a second level shifter group is provided. The first level shifter group includes at least one first level shifter to receive a first input signal. The second level shifter group includes at least one second level shifter to receive a second input signal. The driver sequentially enables the first level shifter group and the second level shifter group to sequentially transfer voltage levels of the first input signal and the second input signal.

### BACKGROUND OF THE INVENTION

1. Field of the Invention

The present invention relates to a display panel. More particularly, the present invention relates to a driver and a control method thereof.

2. Description of Related Art

In a source driver or a gate driver of a liquid crystal display (LCD), the voltage level must be transferred. When a large number of level shifters perform voltage transition at the same time, a large leakage current will occur. As a conductive path has a parasitic resistor, when the leakage current becomes too large, the voltage level at the ground terminal is increased, thus affecting the normal operation of the circuit and the transition ability of the level shifters.

FIG. 1 is a driving circuit diagram in the conventional art. Referring to FIG. 1, the driving circuit 100 includes a plurality of level shifters 111-119, and the resistor R1 represents a parasitic resistor on the path of the ground terminal GND. When voltage transition of input signals V1-V9 occurs (for example, transferring from a high voltage level to a low voltage level or from a low voltage level to a high voltage level), the level shifters 111-119 transit at the same time to change voltage levels of the input signals V1-V9. In general, a leakage current is generated during the transition, and a larger leakage current is generated when many level shift units transit at the same time. The leakage current generated by the level shifters 111-119 generates a voltage drop on the parasitic resistor R1, thus raising the ground terminal voltage of the high level shifters 111-119 and further affecting the transition ability of the level shifters 111-119.

In the circuit design, for example, the driver of the LCD is usually constituted by a plurality of level shift units and high-voltage buffers. Thus, during the transition, the conducted current will be larger, and the voltage drop on the ground terminal will be greater. At this time, the level shift units with poor transition ability will be easily influenced and cannot transit successfully.

### SUMMARY OF THE INVENTION

The present invention is directed to provide a driver, in which the level shifters transit sequentially to avoid generating a high current when performing transition at the same time, so as to ensure that each level shifter successfully performs transition.

The present invention is also directed to provide a driver, in which the latch time of the latches is controlled by a plurality of switches, such that the latches can sequentially latch a signal to avoid the level shifters transit at the same time, thus ensuring that each level shifter can successfully transit.

The present invention is further directed to provide a driver, for sequentially enabling a plurality of level shifters, thus ensuring that each level shifter successfully performs transition.

As embodied and broadly described herein, a driver including a first level shifter group and a second level shifter group is provided. The first level shifter group includes at least one first level shifter to receive a first input signal. The second level shifter group includes at least one second level shifter to receive a second input signal. The driver enables the first level shifter group and the second level shifter group sequentially, so as to sequentially transfer voltage levels of the first input signal and the second input signal.

From another point of view, a driver including a shift register, a first latch unit, a second latch unit, a plurality of switches, and a plurality of level shift units is provided. The first latch unit has a plurality of first latches controlled by the shift register to receive a plurality of signals. The second latch unit has a plurality of second latches for latching the outputs of the first latches. The plurality of switches is respectively coupled between the first latch unit and the second latch unit, and the second latch unit is coupled to the plurality of level shift units. After the first latch unit latches a signal, the plurality of switches is sequentially turned on, such that the plurality of second latches sequentially latches the outputs of the corresponding first latches, and sequentially transfers the levels of the signals through the level shift units.

In another aspect, a driver including a shift register, a first latch unit, a second latch unit, and a plurality of level shift units is provided. The first latch unit includes a plurality of outputs, and the first latch unit is controlled by the shift register to receive a plurality of signals. The second latch unit has a plurality of second latches for latching the outputs of the first latches. The level shift units are respectively coupled to the outputs of the second latches. After the second latch unit latches the outputs of the first latch unit, the driver sequentially enables the plurality of level shift units to sequentially transfer the levels of the signals.

The present invention adopts non-synchronous transition to avoid generating a high current as the level shifters transit at the same time, such that the driving circuit having a plurality of level shifters can operate within a range of normal operating voltage, thus maintaining the ability of voltage transition.

In order to make the aforementioned and other objectives, features, and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional driver.

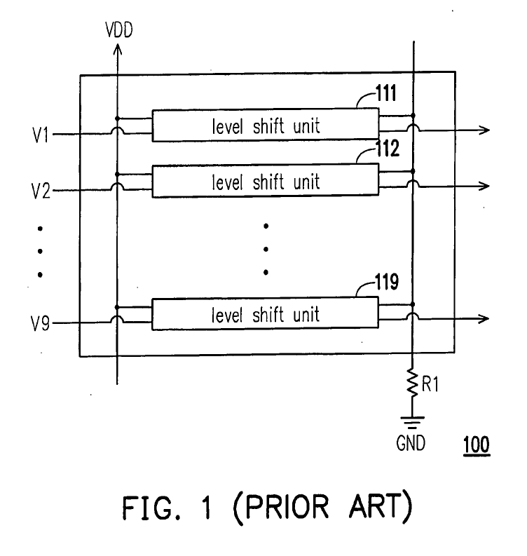

FIG. 2 is a circuit diagram of a driver implemented by grouping according to an embodiment of the present invention.

FIG. 3 is a circuit diagram of a driver implemented by grouping according to another embodiment of the present invention.

FIG. 4 is a circuit diagram of a driver implemented by controlling the latch timing according to another embodiment of the present invention.

FIG. 5 is a circuit diagram of a driver implemented by controlling the transition time by the use of switches according to another embodiment of the present invention.

FIG. 6 is a circuit diagram of a driver implemented by controlling the enable time according to an embodiment of the present invention.

FIG. 7 is a circuit diagram of a driver implemented by controlling the enable time according to another embodiment of the present invention.

### DESCRIPTION OF EMBODIMENTS

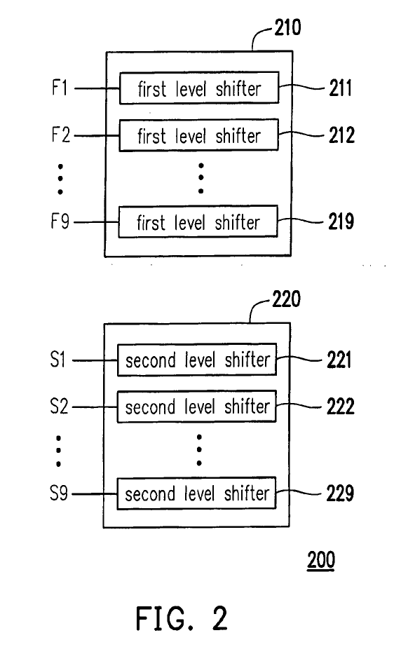

FIG. 2 is a circuit diagram of a driver according to an embodiment of the present invention. The driver 200 includes a plurality of level shifters, and the level shifters are divided into two groups, namely a first level shifter group 210 and a second level shifter group 220. The first level shifter group includes a plurality of first level shifters 211-219 for receiving first input signals F1-F9. Meanwhile, the second level shifter group 220 includes a plurality of second level shifters 221-229 for receiving second input signals S1-S9. When the transition of the first input signals F1-F9 and the second input signals S1-S9 respectively received by the first level shifters 211-219 and the second level shifters 221-229 occurs, the driver 200 sequentially enables the first level shifter group 210 and the second level shifter group 220, so as to sequentially transfer the voltage levels of the first input signals F1-F9 and the second input signals S1-S9. As the level shifters do not transit at the same time, the problem existing in the prior art that the transition fails as the ground level is influenced by as an excessively high current passing through the current path can be avoided.

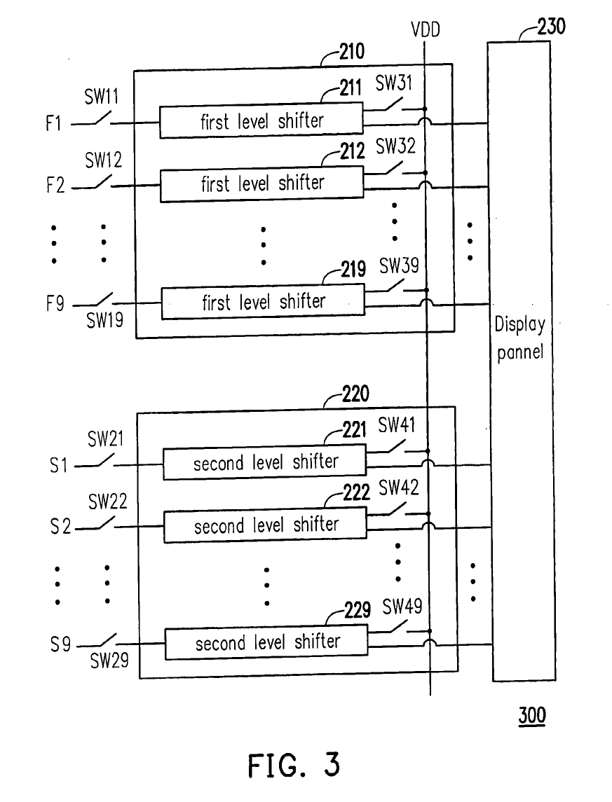

FIG. 3 is a circuit diagram of a driver according to another embodiment of the present invention. The driver 300 includes a first level shifter group 210, a second level shifter group 220, switches SW11-SW19, SW21-SW29, and switches SW31-SW39, SW41-SW49. The switches SW11-SW19 are coupled between the first input signals F1-F9 and the first level shifter group 210, and the switches SW21-SW29 are coupled between the second input signals S1-S9 and the second level shifter group 220. The switches SW31-SW39 are coupled between the plurality of first level shifters 211-219 in the first level shifter group 210 and the operating voltage VDD, and the switches SW41-SW49 are coupled between the plurality of second level shifters 221-229 in the second level shifter group 220 and the operating voltage VDD.

After the voltage levels of the first input signals F1-F9 and the second input signals S1-S9 are transferred by the first level shifter group 210 and the second level shifter group 220, the signals F1-F9 and S1-S9 are output to the display panel 230 for driving the display panel 230. In practical application, the level shifters can be applied to a source driver or a gate driver to change the voltage level of the input signal. For the source driver, the first input signals F1-F9 and the second input signals S1-S9 are a horizontal line of data of the display panel 230 in a frame time.

In this embodiment, the first level shifter group 210 and the second level shifter group 220 are prevented from transiting at the same time in two manners, and the two manners can be used in combination. According to the first implementing manner, the switches SW11-SW19 are turned on first, and then the switches SW21-SW29 are turned on. That is, the transition of the first input signals F1-F9 is performed first, and then the transition of the second input signals S1-SN is performed.

According to the second implementing manner, the switches SW31-SW39 and SW41-SW49 are controlled to enable the first level shifters 211-219 and the second level shifters 221-229 at different time. When the first level shifters 211-219 are enabled, the voltage levels of the first input signals F1-F9 are transferred, and when the second level shifters 221-229 are enabled, the voltage levels of the second input signals S1-S9 is transferred.

Further, the first implementing manner and the second implementing manner can be used in combination. When the first level shifters 211-219 are enabled, the switches SW11-SW19 are turned on in sync, and when the second level shifters 221-229 are enabled, the switches SW21-SW29 are turned on in sync.

In addition, according to a third implementing manner, the switches SW11-SW19, SW21-29 are turned on at different time. That is, the SW11 is turned on first, then the SW12 is turned on . . . and finally the SW29 is turned on. The signals are input into the first level shifters 211-219 and the second level shifters 221-229 at different time to avoid being transited at the same time.

As the transition time of the first level shifter group 210 differs from that of the second level shifter group 220, a transient high current is prevented from being generated to cause voltage drop on the ground terminal, thus ensuring that the first level shifters 211-219 and the second level shifters 221-229 can transit normally.

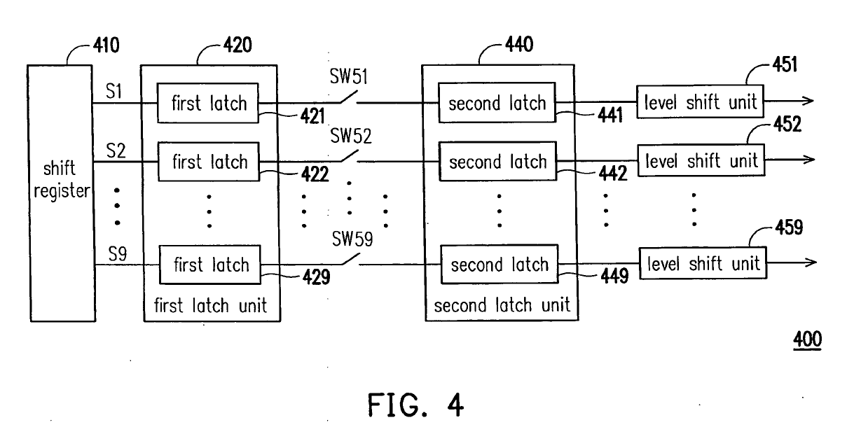

FIG. 4 is a circuit diagram of a driver 400 according to another embodiment of the present invention. The driver 400 of this embodiment includes a shift register 410, a first latch unit 420, a second latch unit 440, a plurality of switches SW51-SW59, and a plurality of level shift units 451-459. The first latch unit 420 includes first latches 421-429 controlled by the shift register 410 to receive a plurality of signals S1-S9. The second latch unit 440 includes second latches 441-449 for latching the outputs of the first latches 421-429. The plurality of switches SW51-SW59 is respectively coupled between the first latches 421-429 and the second latches 441-449, and the output ends of the second latches 441-449 are respectively coupled to the plurality of level shift units 451-459.

After the first latch unit 420 receives the latch signals S1-SN, the switches SW51-SW59 are turned on sequentially, such that the second latch unit 440 sequentially latches the outputs of the first latches 421-429, and sequentially transfers the voltage level of the signals S1-S9 through the level shift units 451-459. As the plurality of switches SW51-SW59 is not turned on at the same time, the level shift units 451-459 will not transit at the same time.

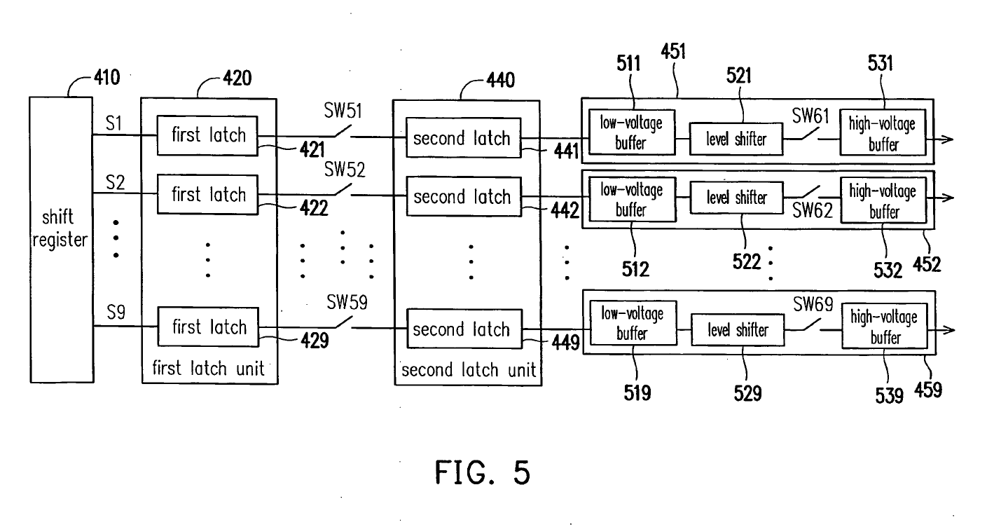

In a common circuit architecture, a leakage current may be generated when the level shifters transit, and the same circumstance also exists in the buffers. The technical means of the above embodiments can be applied to the level shift units having buffers. Hereinafter, the circuit architecture of the level shift units is further illustrated. Referring to FIG. 5, it is a circuit diagram of a driver according to another embodiment of the present invention. FIG. 5 is different from FIG. 4 in terms of the level shift units 451-459. Taking the level shift unit 451 as an example, the level shift unit 451 includes a low-voltage buffer 511, a level shifter 521, a high-voltage buffer 531, and a switch SW61. The level shifter 521 is coupled to the output end of the low-voltage buffer 511, and the switch SW61 is coupled between the level shifter 521 and the high-voltage buffer 531. The circuit architectures of the level shift units 452-459 are the same, and the details will not be described herein again.

The switches SW61-SW69 are turned off when the corresponding level shifters 521-529 transit, and turned on after the transition to delay the transition time of the high-voltage buffers 531-539. Taking the level shift unit 451 for example, the switch SW61 is turned off when the level shifter 521 transits, and turned on after the transition to delay the transition time of the high-voltage buffer 531, so as to prevent a large leakage current from being generated as the level shifter 521 and the high-voltage buffer 531 transit at the same time, thus avoiding influencing the normal transition of the level shifter 521. The details of the operation of the embodiment in FIG. 5 can refer to the embodiment in FIG. 4, and will not be described herein again.

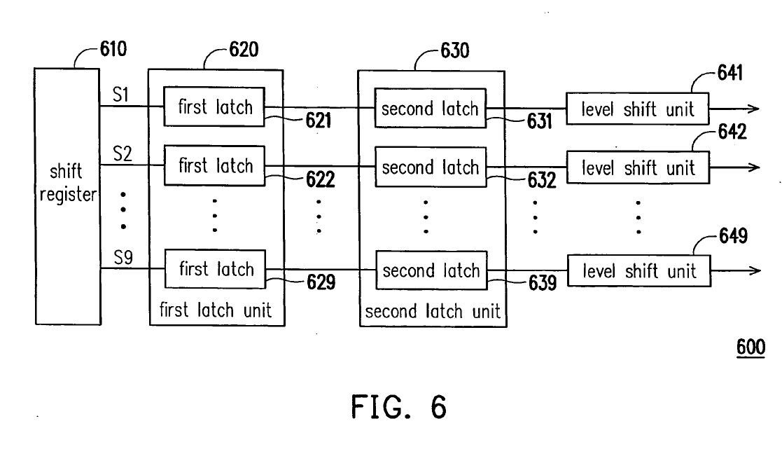

FIG. 6 is a circuit diagram of a driver according to another embodiment of the present invention. The driver 600 includes a shift register 610, a first latch unit 620, a second latch unit 630, and level shift units 641-649. The first latch unit 620 includes a plurality of first latches 621-629 controlled by the shift register 610 to receive the signals S1-S9. The second latch unit 630 includes a plurality of second latches 631-639 for latching the outputs of the first latch unit 620, and the level shift units 641-649 are coupled to the outputs of the second latch unit 63 0.

In this embodiment, the enable time (the time for providing a power supply) of the level shift units 641-649 is controlled to adjust the transition time of individual level shift units 641-649. When the second latch unit 630 latches the outputs of the first latch unit 620, the driver 600 sequentially enables the level shift units 641-649, so as to sequentially transfer the levels of the signals. For the enable sequence, the level shift units can be enabled in different batches or enabled individually in sequence so long as it is prevented to enable a large number of level shift units at the same time. Moreover, the enable sequence or the number of the level shift units enabled at the same time is not limited in the embodiment.

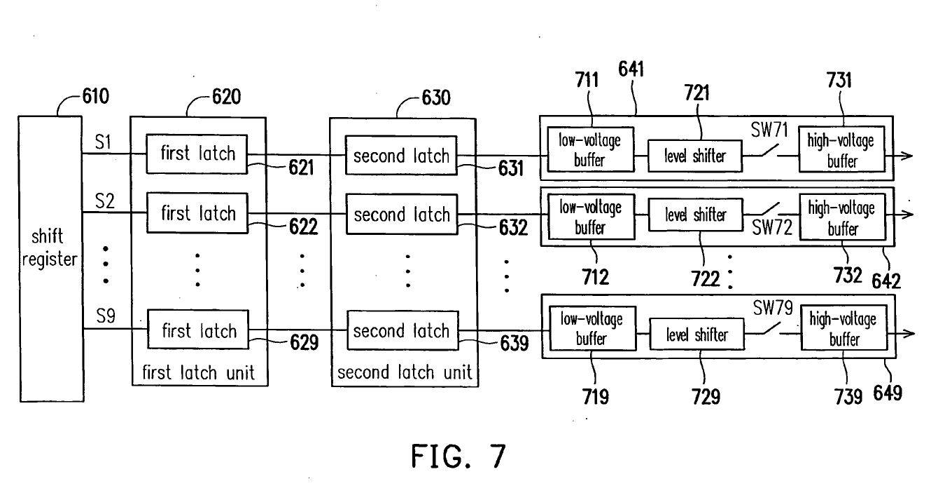

FIG. 7 is a circuit diagram of the driver according to the embodiment of FIG. 6, and the inner circuit architecture of each of the level shift units 641-649 is illustrated in FIG. 7, so as to further illustrate the operation manner when each of the level shift units 641-649 has a low-voltage buffer and a high-voltage buffer.

Referring to FIG. 7, taking the level shift unit 641 as an example, the level shift unit 641 includes a low-voltage buffer 711, a level shifter 721, a switch SW71, and a high-voltage buffer 731. The low-voltage buffer 711 is coupled to the corresponding second latch 631, the level shifter 721 is coupled to the output end of the low-voltage buffer 711, and the high-voltage buffer 731 is coupled to the output end of the level shifter 721 through the switch SW71. The switch SW71 is turned off when the level shifter 721 transit, and turned on after the transition to delay the transition time of the high-voltage buffer 731, thus ensuring that the level shifter 721 successfully performs transition. The circuit architecture and operation manner of the level shift units 642-649 are similar, and the details will not be described herein again.

The level shift units 641-649 are enabled by controlling the power supply manner of the level shifters 721-729. Through the turn-on time of the switches SW71-SW79 and the timing of signal transmission of the first latch unit 620 and the second latch unit 630, the transition time of the level shifters 641-649, the low-voltage buffers 711-719, and the high-voltage buffers 731-739 is adjusted, so as to avoid transiting at the same time to influence the voltage drop of the ground terminal.

The above embodiments provide many implementing manners to avoid transiting at the same time, for example, by a grouping manner (referring to the illustrations of FIG. 2, FIG. 3), or controlling the signal latch timing of the latches (referring to the illustration of FIG. 4), and controlling the transition time of the high-voltage buffer by the use of the switches (referring to FIG. 5). A manner of alternating the transition time through the enable time is illustrated in FIG. 6, FIG. 7. The above implementing manners can be used independently or in combination to achieve the technical effect of avoiding transition at the same time. As such, it can effectively avoid generating an excessively large transient leakage current to raise the voltage level of the ground terminal, thus preventing influencing the transition ability of the level shifters. Those of ordinary skill in the art can easily deduce the application manner of the present invention according to the disclosure thereof, and the details will not be described herein again.

In view of the above, the present invention employs non-synchronous transition to avoid generating a high current when a great many level shifters or buffers transit at the same time, thus avoiding raising the voltage level of the ground terminal. As such, the driving circuit having a plurality of level shifters can operate within the range of normal operating voltage, and the ability of voltage transition of the level shifters is maintained.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A driver, comprising:
a first level shifter group, having at least one first level shifter, the first level shifter receiving a corresponding first input signal; and
a second level shifter group, having at least one second level shifter, the second level shifter receiving a corresponding second input signal;
wherein the driver sequentially enables the first level shifter group and the second level shifter group, so as to sequentially transfer voltage levels of the first input signal and the second input signal.

2. The driver as claimed in claim 1, further comprising at least one first switch coupled between the at least one first level shifter and the first input signal, wherein when the first level shifter group is enabled, the first switch is turned on.

3. The driver as claimed in claim 1, further comprising at least one second switch coupled between the second level shifter and the second input signal, wherein when the second level shifter group is enabled, the second switch is turned on.

4. The driver as claimed in claim 1, further comprising a plurality of switches for respectively controlling the operating voltages of the first level shifter and the second level shifter, so as to enable the first level shifter and the second level shifter.

5. The driver as claimed in claim 1, wherein the driver is used to drive a display panel, and the first input signal and the second input signal are a horizontal line of data of the display panel in a frame time.

6. A driver, comprising:
a shift register;
a first latch unit, having a plurality of first latches controlled by the shift register to receive a plurality of signals;
a second latch unit, having a plurality of second latches, for latching the outputs of the first latches;
a plurality of switches, respectively coupled between the first latches and the second latches; and
a plurality of level shift units, respectively coupled to the second latches;
wherein after the first latch unit latches the signals, the switches are sequentially turned on to make the second latches sequentially latch the outputs of the first latches, and therefore sequentially transfer the levels of the signals through the level shift units.

7. The driver as claimed in claim 6, wherein each of the level shift units comprises:
a low-voltage buffer, coupled to a corresponding one of the second latches;
a level shifter, coupled to the output of the low-voltage buffer; and
a high-voltage buffer, coupled to the output of the level shifter.

8. The driver as claimed in claim 7, wherein each of the level shift units further comprises:
a first switch, coupled between the level shifter and the high-voltage buffer, wherein the first switch is turned off when the level shifter performs transition, and is turned on after the level shifter finishes the transition, so as to delay the transition time of the high-voltage buffer.

9. A driver, comprising:
a shift register;
a first latch unit, having a plurality of outputs, wherein the first latch unit is controlled by the shift register to receive a plurality of signals;
a second latch unit, having a plurality of second latches, for latching the outputs of the first latch unit; and
a plurality of level shift units, respectively coupled to the outputs of the second latch unit;
wherein after the second latch unit latches the outputs of the first latch unit, the driver sequentially enables the level shift units to sequentially transfer the levels of the signals.

10. The driver as claimed in claim 9, wherein each of the level shift units comprises:
a low-voltage buffer, coupled to a corresponding one of the second latches;
a level shifter, coupled to the output of the low-voltage buffer; and
a high-voltage buffer, coupled to the output of the level shifter.

11. The driver as claimed in claim 10, wherein each of the level shift units further comprises:
a first switch, coupled between the level shifter and the high-voltage buffer, wherein the first switch is turned off when the level shifter performs transition, and is turned on after the level shifter finishes the transition, so as to delay the transition time of the high-voltage buffer.
